(19) United States
(12) Patent Application Publication
(10) Pub. No.: US 2023/0200067 A1
(43) Pub. Date: Jun. 22, 2023

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventor: Jung Hyeong Kim, Icheon-si Gyeonggi-do (KR)

(73) Assignee: SK hynix Inc., Icheon-si Gyeonggi-do (KR)

(21) Appl. No.: 17/730,896

(22) Filed: Apr. 27, 2022

(30) Foreign Application Priority Data
Dec. 17, 2021 (KR) 10-2021-0182122

(51) Int. Cl. H01L 27/11582; H01L 27/11556; H01L 25/065; H01L 25/18; H01L 23/00; H01L 25/00

(52) U.S. Cl. CPC H01L 27/11582; H01L 27/11556; H01L 25/0657; H01L 25/18; H01L 24/08; H01L 24/80; H01L 25/50; H01L 2224/08145; H01L 2224/80895; H01L 2224/80896; H01L 2924/1431; H01L 2924/14511

(57) ABSTRACT

Provided herein is a semiconductor memory device and a method of manufacturing the semiconductor memory device. The semiconductor memory device includes a gate stacked body including interlayer insulating layers and conductive patterns that are alternately stacked in a vertical direction on a substrate, a channel structure penetrating at least a portion of the gate stacked body, and an upper surface of the channel structure left exposed by the gate stacked body.

### CROSS-REFERENCE TO RELATED APPLICATION

The present application claims priority under 35 U.S.C. § 119(a) to Korean patent application number 10-2021-0182122 filed on Dec. 17, 2021, in the Korean Intellectual Property Office, the entire disclosure of which is incorporated by reference herein.

### BACKGROUND

### 1. Technical Field

Various embodiments of the present disclosure relate to an electronic device, and more particularly to a semiconductor memory device including a channel structure and a method of manufacturing the semiconductor memory device.

### 2. Related Art

Recently, the paradigm for a computer environment has been converted into ubiquitous computing so that computer systems can be used anytime and anywhere. Due to this, the use of portable electronic devices such as mobile phones, digital cameras, and notebook computers has rapidly increased. In general, such portable electronic devices use a memory system which employs a semiconductor memory device, in other words, use a data storage device. The data storage device is used as a main memory device or an auxiliary memory device for portable electronic devices.

A data storage device using a semiconductor memory device is advantageous in that, since there is no mechanical driving part, stability and durability are excellent, an information access speed is high, and power consumption is low. The data storage device, as examples of the memory system having such advantages, includes a universal serial bus (USB) memory device, memory cards having various interfaces, a solid state drive (SSD), etc.

Semiconductor memory devices are classified into a volatile memory device and a nonvolatile memory device.

Such a nonvolatile memory device has comparatively low write and read speed, but retains data stored therein even when the supply of power is interrupted. Therefore, the nonvolatile memory device is used to store data to be retained regardless of whether power is supplied. Representative examples of the nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. The flash memory is classified into a NOR type and a NAND type.

### SUMMARY

An embodiment of the present disclosure may provide for a semiconductor memory device. The semiconductor memory device may include a gate stacked body including interlayer insulating layers and conductive patterns that are alternately stacked in a vertical direction on a substrate, a channel structure penetrating at least a portion of the gate stacked body, and an upper surface of the channel structure left exposed by the gate stacked body, a memory layer configured to enclose a sidewall of the channel structure, and a source line structure formed on the gate stacked body to contact the upper surface of the channel structure, wherein the channel structure may include a first channel layer extending in a vertical direction, and a second channel layer configured to enclose a sidewall of the first channel layer adjacent to an uppermost conductive pattern, among the plurality of conductive patterns.

An embodiment of the present disclosure may provide for a semiconductor memory device. The semiconductor memory device may include a gate stacked body including interlayer insulating layers and conductive patterns that are alternately stacked in a vertical direction on a substrate, a channel structure penetrating at least a portion of the gate stacked body, and an upper surface of the channel structure left exposed by the gate stacked body, a memory layer configured to enclose a sidewall of the channel structure, and a source line structure formed on the gate stacked body to contact the upper surface of the channel structure, wherein the channel structure may include a core insulating layer extending in the vertical direction, a first channel layer configured to enclose an outer wall of the core insulating layer, and a second channel layer configured to enclose a sidewall of the first channel layer adjacent to an uppermost conductive pattern, among the plurality of conductive patterns, and wherein the memory layer may include a gate insulating layer disposed between the second channel layer and the uppermost conductive pattern.

An embodiment of the present disclosure may provide for a method of manufacturing a semiconductor memory device. The method may include forming a gate stacked body including interlayer insulating layers and conductive patterns that are alternately stacked in a vertical direction on a substrate, forming a plurality of channel structures, each including a core insulating layer penetrating at least a portion of the gate stacked body and having an end extending into the first substrate, a first channel layer configured to enclose a sidewall and the end of the core insulating layer, and a memory layer extending from an area between the first channel layer and the gate stacked body to an area between an end of the channel layer and the first substrate, causing ends of the plurality of channel structures to protrude from the gate stacked body by removing the first substrate, exposing the first channel layer by removing the memory layer, among the protruding ends of the channel structures, sequentially forming a second channel layer and a gate insulating layer along a surface of the exposed first channel layer, and forming a conductive pattern on the gate stacked body between the protruding channel structures.

### BRIEF DESCRIPTION OF THE DRAWINGS

FIG. 1 is a block diagram illustrating a semiconductor memory device according to an embodiment of the present disclosure.

FIG. 2 is a circuit diagram for explaining a memory cell array of FIG. 1.

FIG. 3 is a perspective view schematically illustrating a semiconductor memory device according to an embodiment of the present disclosure.

FIG. 4 is a sectional view for explaining the memory cell array of FIG. 1.

FIGS. 5A, 5B, 5C, 5D, 5E, 5F, 6, 7, and 8A, 8B, 8C, 8D, 8E, and 8F are sectional views illustrating a method of manufacturing a semiconductor memory device according to an embodiment of the present disclosure.

FIG. 9 is a block diagram illustrating the configuration of a memory system according to an embodiment of the present disclosure.

FIG. 10 is a block diagram illustrating the configuration of a computing system according to an embodiment of the present disclosure.

### DETAILED DESCRIPTION

Specific structural or functional descriptions in the embodiments of the present disclosure introduced in this specification or application are exemplified to describe embodiments according to the concept of the present disclosure. The embodiments according to the concept of the present disclosure may be practiced in various forms, and should not be construed as being limited to the embodiments described in the specification or application.

Various embodiments of the present disclosure will now be described with reference to the accompanying drawings. Various embodiments of the present disclosure are directed to a semiconductor memory device in which a channel layer corresponding to a select transistor can be formed in a channel structure protruding to penetrate at least a portion of a gate stacked body, and a method of manufacturing the semiconductor memory device.

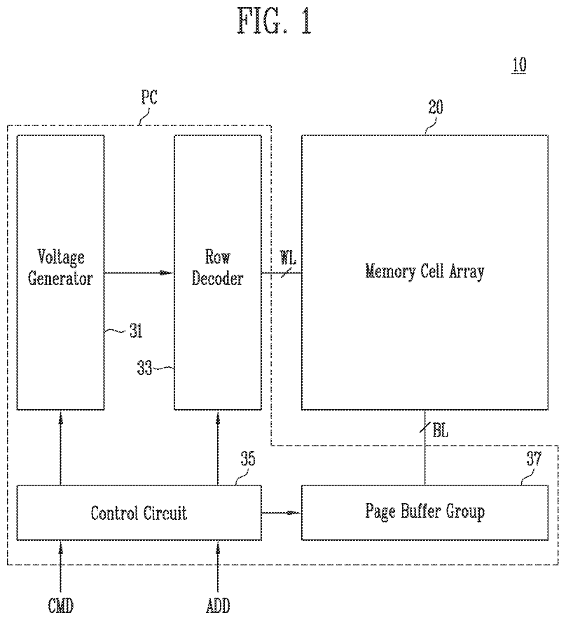

FIG. 1 is a block diagram illustrating a semiconductor memory device according to an embodiment of the present disclosure.

Referring to FIG. 1, a semiconductor memory device 10 includes a peripheral circuit PC and a memory cell array 20.

The peripheral circuit PC may control a program operation of storing data in the memory cell array 20, a read operation of outputting data stored in the memory cell array 20, and an erase operation of erasing data stored in the memory cell array 20.

In an embodiment, the peripheral circuit PC may include a voltage generator 31, a row decoder 33, a control circuit 35, and a page buffer group 37.

The memory cell array 20 may include a plurality of memory blocks. The memory cell array 20 may be coupled to the row decoder 33 through word lines WL, and may be coupled to the page buffer group 37 through bit lines BL.

The control circuit 35 may control the voltage generator 31, the row decoder 33, and the page buffer group 37 in response to a command CMD and an address ADD.

The voltage generator 31 may generate various operating voltages, such as an erase voltage, a ground voltage, a program voltage, a verify voltage, a pass voltage, and a read voltage, which are used for a program operation, a read operation, and an erase operation, under the control of the control circuit 35.

The row decoder 33 may select a memory block under the control of the control circuit 35. The row decoder 33 may apply the operating voltages to the word lines WL coupled to the selected memory block.

The page buffer group 37 may be coupled to the memory cell array 20 through the bit lines BL. The page buffer group 37 may temporarily store data received from an input/output circuit (not illustrated) under the control of the control circuit 35 during a program operation. The page buffer group 37 may sense voltages or currents of the bit lines BL under the control of the control circuit 35 during a read operation or a verify operation. The page buffer group 37 may select the bit lines BL under the control of the control circuit 35.

Structurally, the memory cell array 20 may overlap a part of the peripheral circuit PC.

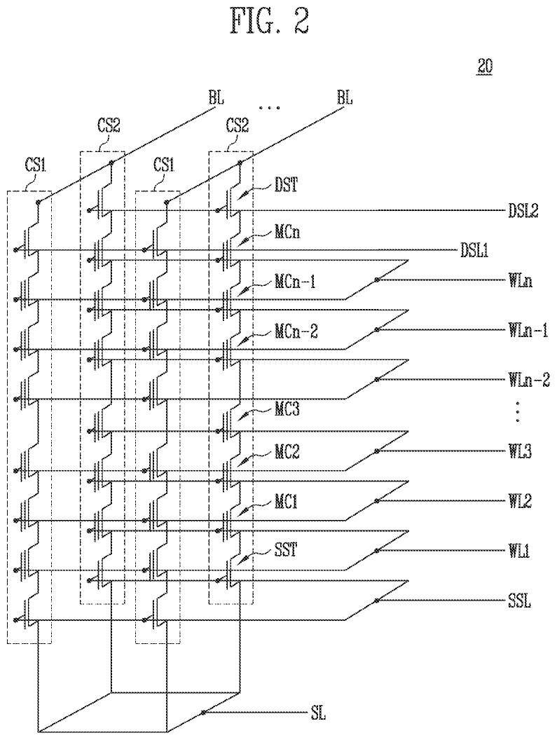

FIG. 2 is a circuit diagram for explaining the memory cell array of FIG. 1.

Referring to FIG. 2, the memory cell array 20 may include a plurality of cell strings CS1 and CS2 coupled between a source line SL and a plurality of bit lines BL. The plurality of cell strings CS1 and CS2 may be coupled in common to a plurality of word lines WL1 to WLn.

Each of the plurality of cell strings CS1 and CS2 may include at least one source select transistor SST coupled to the source line SL, at least one drain select transistor DST coupled to the corresponding bit line BL, and a plurality of memory cells MC1 to MCn connected in series to each other between the source select transistor SST and the drain select transistor DST.

Gates of the plurality of memory cells MC1 to MCn may be respectively coupled to the plurality of word lines WL1 to WLn stacked to be spaced apart from each other. The plurality of word lines WL1 to WLn may be arranged between a source select line SSL and two or more drain select lines DSL1 and DSL2. The two or more drain select lines DSL1 and DSL2 may be spaced apart from each other at the same level.

A gate of the source select transistor SST may be coupled to the source select line SSL. A gate of the drain select transistor DST may be coupled to a drain select line corresponding to the gate of the drain select transistor DST.

The source line SL may be coupled to a source of the source select transistor SST. A drain of the drain select transistor DST may be coupled to a bit line corresponding to the drain of the drain select transistor DST.

The plurality of cell strings CS1 and CS2 may be divided into string groups coupled to the two or more drain select lines DSL1 and DSL2, respectively. Cell strings coupled to the same word line and the same bit line may be independently controlled by different drain select lines. Further, cell strings coupled to the same drain select line may be independently controlled by different bit lines.

In an embodiment, two or more drain select lines DSL1 and DSL2 may include a first drain select line DSL1 and a second drain select line DSL2. The plurality of cell strings CS1 and CS2 may include first cell strings CS1 of a first string group coupled to the first drain select line DSL1 and second cell strings CS2 of a second string group coupled to the second drain select line DSL2.

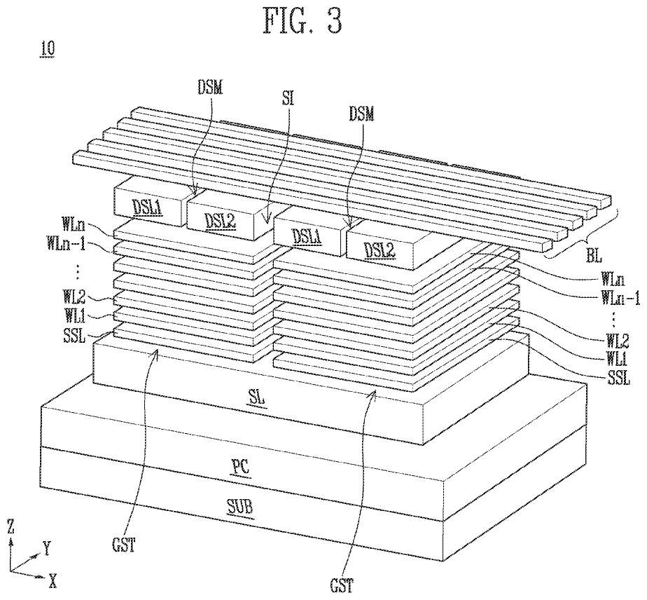

FIG. 3 is a perspective view schematically illustrating a semiconductor memory device according to an embodiment of the present disclosure.

Referring to FIG. 3, a semiconductor memory device 10 may include a peripheral circuit PC arranged on a substrate SUB and gate stacked bodies GST overlapping the peripheral circuit PC.

Each of the gate stacked bodies GST may include a source select line SSL, a plurality of word lines WL1 to WLn, and two or more drain select lines DSL1 and DSL2 separated from each other at the same level by a separation structure DSM.

The source select line SSL and the plurality of word lines WL1 to WLn may extend in a first direction X and a second direction Y, and may be formed in planar shapes parallel to each other on the upper surface of the substrate SUB. The first direction X may be the direction of an X axis in an XYZ coordinate system, and the second direction Y may be the direction of a Y axis in the XYZ coordinate system.

The plurality of world lines WL1 to WLn may be stacked to be spaced apart from each other in a third direction Z. The third direction Z may be the direction of a Z axis in the XYZ coordinate system. The plurality of word lines WL1 to WLn may be arranged between the two or more drain select lines DSL1 and DSL2 and the source select line SSL.

The gate stacked bodies GST may be separated from each other by a slit SI. The separation structure DSM may be formed to be shorter than the slit SI in the third direction Z, and may overlap the plurality of word lines WL1 to WLn.

Each of the separation structure DSM and the slit SI may extend in a linear shape, a zigzag shape, or a wave shape. The width of each of the separation structure DSM and the slit SI may be variously changed according to design specifications.

The source select line SSL according to an embodiment may be arranged closer to the peripheral circuit PC than the two or more drain select lines DSL1 and DSL2.

The semiconductor memory device 10 may include a source line SL disposed between the gate stacked bodies GST and the peripheral circuit PC and a plurality of bit lines BL, spaced farther apart from the peripheral circuit PC than the source line SL. The gate stacked bodies GST may be disposed between the plurality of bit lines BL and the source line SL.

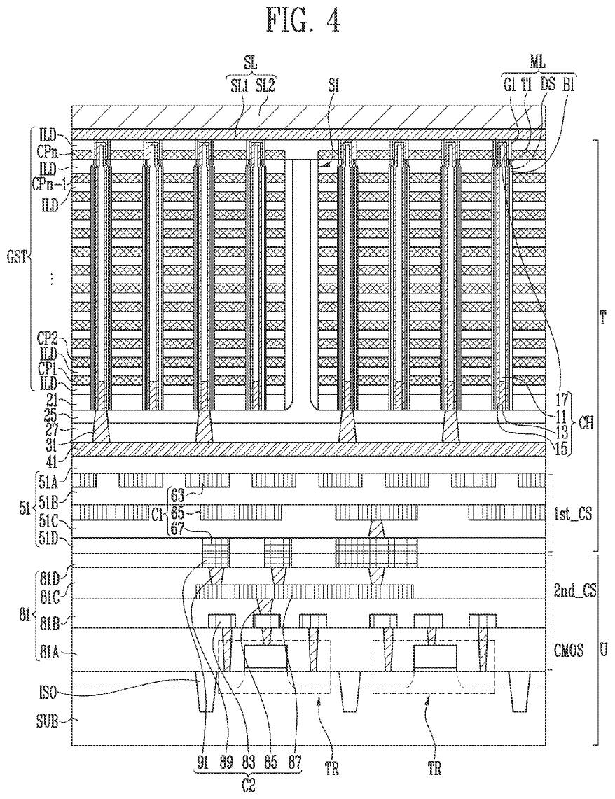

FIG. 4 is a sectional view for explaining the memory cell array of FIG. 1.

Referring to FIG. 4, the memory cell array may be configured such that a lower structure U and an upper structure T are adhered to each other and a source line structure SL is disposed on the upper structure T.

The upper structure T may include gate stacked bodies GST separated from each other by a slit SI, channel structures CH penetrating at least portions of the gate stacked bodies GST, a memory layer ML extending along the sidewall of each of the channel structures CH, and a bit line 41 and a first coupling structure 1st_CS, which are disposed below the gate stacked bodies GST.

Each gate stacked body GST may include interlayer insulating layers ILD and conductive patterns CP1 to CPn that are alternately stacked in a vertical direction. Each of the conductive patterns CP1 to CPn may include various conductive materials, such as a doped silicon layer, a metal layer, a metal silicide layer, and a barrier layer, and may include two or more types of conductive materials. For example, each of the conductive patterns CP1 to CPn may include tungsten and a titanium nitride layer TiN configured to enclose the surface of the tungsten. Tungsten is a low-resistance material and is capable of decreasing the resistance of the conductive patterns CP1 to CPn. The titanium nitride layer TiN may be a barrier layer, and may prevent tungsten and the interlayer insulating layers ILD from directly contacting each other.

The first conductive pattern CP1 adjacent to the bit line 41, among the conductive patterns CP1 to CPn, may be used as a drain select line DSL. In other embodiments, conductive patterns of two or more layers, which are adjacent to the bit line 41 and are successively stacked, may be used as drain select lines. Among the conductive patterns CP1 to CPn, the n-th conductive pattern CPn adjacent to the first source layer SL1 and the second source layer SL2 may be used as a source select line SSL. In various embodiments, conductive patterns of two or more layers, which are adjacent to the first source layer SL1 and the second source layer SL2 and are successively stacked, may be used as source select lines. In an embodiment, the n-th conductive pattern CPn adjacent to the adjacent to the first source layer SL1 and the second source layer SL2 may be an uppermost conductive pattern. In an embodiment, conductive patterns of two or more layers, which are adjacent to the first source layer SL1 and the second source layer SL2 and are successively stacked, may be a group of uppermost conductive patterns. The conductive patterns (e.g., CP2 to CPn−1), which are adjacent to each other in a vertical direction and are disposed between the drain select line and the source select line, may be used as word lines WL1 to WLn, described above with reference to FIG. 2. In an embodiment, the conductive patterns (e.g., CP2 to CPn−1), which are adjacent to each other in a vertical direction and are disposed between the drain select line and the source select line, may be identified as other conductive patterns. In an embodiment, a second channel layer 17 may be configured to enclose a sidewall of a first channel layer 15 at a level where an uppermost conductive pattern (i.e., CPn) intersects with the second channel layer 17 enclosing the sidewall of the first channel layer 15.

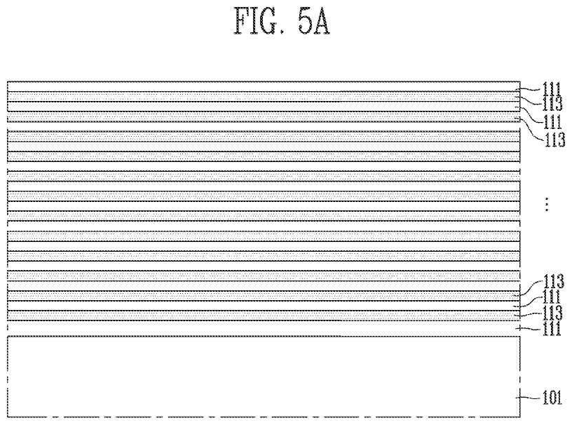

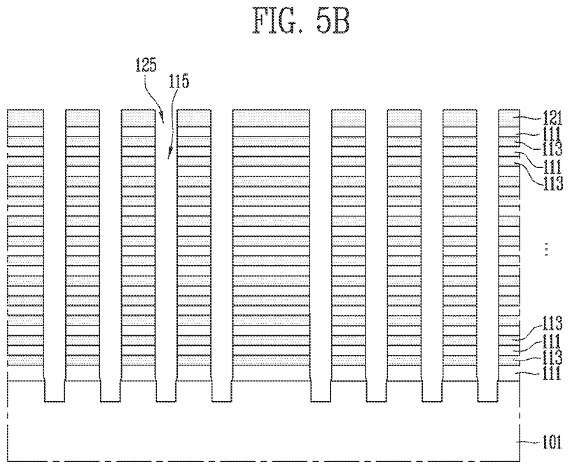

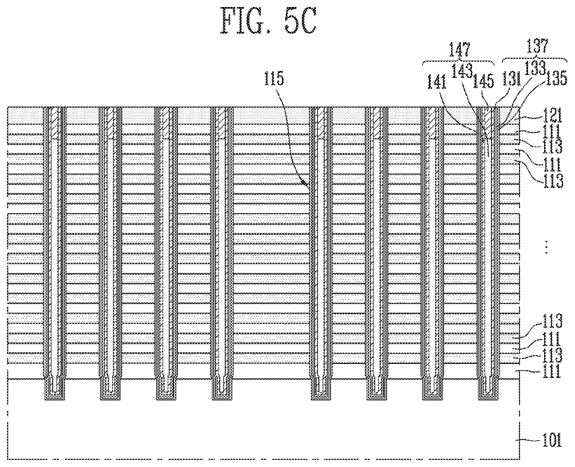

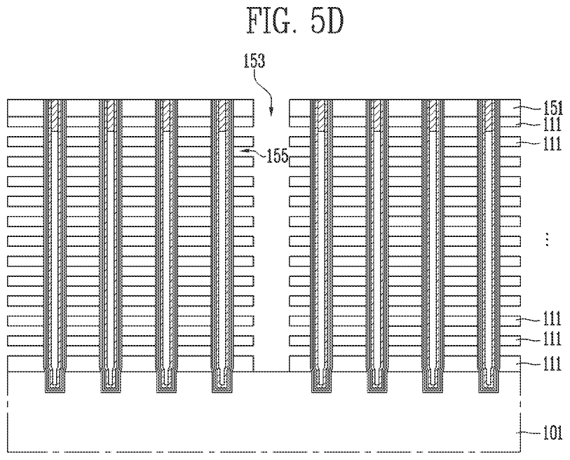

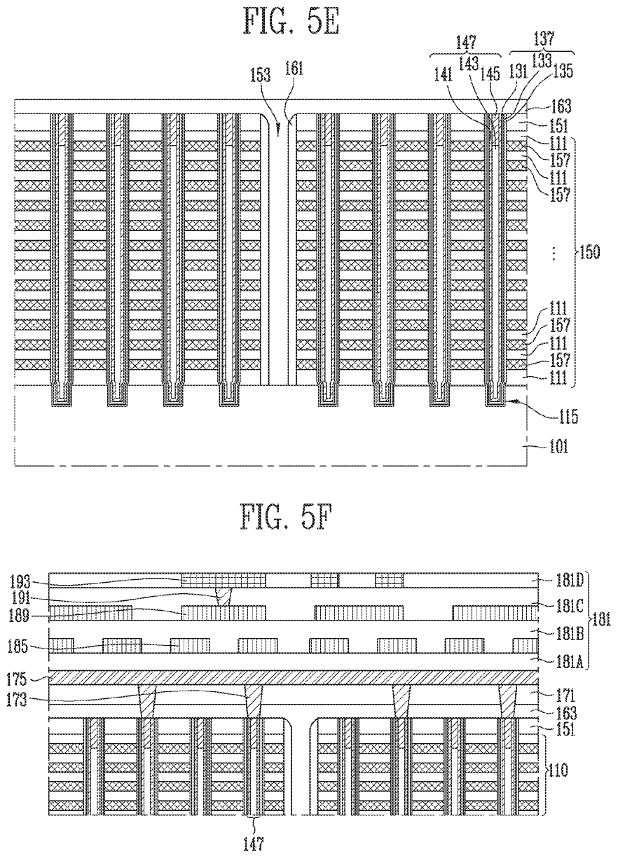

Each channel structure CH may vertically penetrate at least a portion of the corresponding gate stacked body GST, and the height of a first end of the channel structure CH may be identical to that of the upper portion of the gate stacked body GST. Each channel structure CH may be formed in a hollow type structure formed from the gate stacked body GST, and the channel structure CH may protrude from the gate stacked body GST. In an embodiment, each channel structure CH may be formed in a channel hole, for example channel hole 115 shown below in FIG. 5B. The channel structure CH may include a core insulating layer 11 filling a central region, a doped semiconductor layer 13 disposed under the core insulating layer 11, a first channel layer 15 configured to enclose the sidewall surfaces of the core insulating layer 11 and the doped semiconductor layer 13 and the upper surface of the core insulating layer 11, and a second channel layer 17 disposed on the upper portion of the channel structure CH and configured to enclose the sidewall surface and the upper surface of a first end of the first channel layer 15. The first channel layer 15 and the second channel layer 17 are used as the channel area of the cell string corresponding thereto. The first channel layer 15 may be formed of a semiconductor material. In an embodiment, the first channel layer 15 may include a silicon layer. In an embodiment, the first channel layer 15 may be an undoped polysilicon layer. The second channel layer 17 enclosing the first end of the first channel layer 15 may be a channel area corresponding to a source select transistor, and may include a doped polysilicon layer. That is, the second channel layer 17 may be formed to enclose the sidewall surface of the first channel layer 15 and the upper surface of the first channel layer 15 in the channel area corresponding to the source select transistor. Accordingly, the sidewall surface of an upper portion and the upper surface of the channel structure CH may form a structure in which the second channel layer 17 is formed on an outer wall of the channel structure CH.

The memory layer ML may be formed to enclose the surface of the channel structure CH. The memory layer ML may include a tunnel insulating layer TI configured to enclose an outer wall of the first channel layer 15 of the channel structure CH, a data storage layer DS configured to enclose an outer wall of the tunnel insulating layer TI, a blocking insulating layer BI configured to enclose an outer wall of the data storage layer DS, and a gate insulating layer GI configured to enclose the sidewall surface of the second channel layer 17. The gate insulating layer GI may be excluded from the components included in the memory layer ML. The memory layer ML may extend from the channel structure CH in a vertical direction. Also, the memory layer ML may be formed to have the same height as the channel structure CH. The memory layer ML may be defined as a component included in the channel structure CH.

The bit line 41 may be disposed below the gate stacked body GST. The bit line 41 may be coupled to the channel structures CH through contact plugs 31 penetrating at least portions of a plurality of insulating layers 21, 25, and 27. The bit line 41 may be spaced apart from the substrate SUB by a first insulating structure 51 and a second insulating structure 81.

The first coupling structure 1st_CS may include the first insulating structure 51 and first connection structures C1 formed in the first insulating structure 51. The first connection structures C1 may include various conductive patterns 63, 65, and 67. The first insulating structure 51 may include two or more insulating layers 51A to 51D stacked between the bit line 41 and the second insulating structure 81.

The lower structure U may include a complementary metal oxide semiconductor (CMOS) circuit structure CMOS including a plurality of transistors TR formed on the substrate SUB and a second coupling structure 2nd_CS formed on the CMOS circuit structure CMOS. Isolation layers ISO may be disposed in the substrate SUB, and may isolate junctions of the plurality of transistors TR from each other.

The second coupling structure 2nd_CS may include the second insulating structure 81 formed on the substrate SUB and second connection structures C2 formed in the second insulating structure 81. The second connection structures C2 may respectively include various conductive patterns 83, 85, 87, 89, and 91 embedded in the second insulating structure 81. The second insulating structure 81 may include two or more insulating layers 81A to 81D that are sequentially stacked.

The upper structure T and the lower structure U may have a structure in which they are adhered to each other through a bonding process. For example, exposed conductive patterns 67 of the first coupling structure 1st_CS of the upper structure T and exposed conductive patterns 91 of the second coupling structure 2nd_CS of the lower structure U may be disposed to face each other, and may be adhered to each other. The conductive patterns 67 and the conductive patterns 91 may be defined as patterns for bonding metal.

The source line structure SL may be disposed on the upper structure T. The source line structure SL may be configured to include the first source layer SL1 and the second source layer SL2. The first source layer SL1 may be implemented as a doped polysilicon layer. The first source layer SL1 may be directly, electrically, and physically connected to the second channel layer 17, which is exposed by penetrating at least a portion of the gate stacked body GST. The second source layer SL2 may be formed on the first source layer SL1. The second source layer SL2 may be formed of a metal material having low resistance. For example, the second source layer SL2 may be formed of tungsten W, thus reducing the resistance of the source line structure. A titanium (Ti) layer or a titanium nitride (TiN) layer may be further included between the first source layer SL1 and the second source layer SL2.

FIGS. 5A to 5F, 6, 7, and 8A to 8F are sectional views for explaining a method of manufacturing a semiconductor memory device according to an embodiment of the present disclosure.

FIGS. 5A to 5F are sectional views for explaining the step of forming a memory cell array, a first line array, and first connection structures on a first substrate.

Referring to FIG. 5A, first material layers 111 and second material layers 113 may be alternately stacked on top of one another on a first substrate 101.

The first substrate 101 may be formed of a material having an etch rate different from that of the first material layers 111 and the second material layers 113. For example, the first substrate 101 may include silicon.

In an embodiment, the first material layers 111 may be made of an insulating material for the interlayer insulating layers ILD, described above with reference to FIG. 4. The second material layers 113 may be formed of a material having an etch rate different from that of the first material layers 111. For example, the first material layers 111 may include silicon oxide, and the second material layers 113 may include silicon nitride. Although the following drawings illustrate embodiments in which the first material layers 111 are implemented as insulating layers and the second material layers 113 are implemented as sacrificial layers, the present disclosure is not limited thereto. The material properties of the first material layers 111 and the second material layers 113 may be variously changed. For example, the first material layers 111 may be made of an insulating material for the interlayer insulating layers ILD, described above with reference to FIG. 4, and the second material layers 113 may be made of a conductive material for the conductive patterns CP1 to CPn, described above with reference to FIG. 4.

Referring to FIG. 5B, a first mask pattern 121 having therein first openings 125 may be formed on a stacked structure of the first material layers 111 and the second material layers 113. Thereafter, channel holes 115 passing through at least portions of the first material layers 111 and the second material layers 113 may be formed through the first openings 125 in the first mask pattern 121. The channel holes 115 may extend into the first substrate 101 to a certain depth partway through the first substrate 101. The channel holes 115 may be formed in various shapes depending on the etch material that is used to form the channel holes 115.

In an embodiment, the channel holes 115 may be formed using a first etch material. The etch speeds of the first material layers 111 and the second material layers 113 corresponding to the first etch material may be higher than the etch speed of the first substrate 101 corresponding to the first etch material. As a result, the widths of ends of the channel holes 115 extending into the first substrate 101 may be formed to be smaller than those of the channel holes 115 passing through the first material layers 111 and the second material layers 113.

Referring to FIG. 5C, a memory layer 137 and a channel structure 147 may be formed in each of the channel holes 115. The sidewall of the channel structure 147 and the end of the channel structure 147 extending into the first substrate 101 may be enclosed by the memory layer 137.

The step of forming the memory layer 137 may include the step of sequentially stacking a blocking insulating layer 135, a data storage layer 133, and a tunnel insulating layer 131 on the surfaces of the channel holes 115. The blocking insulating layer 135, the data storage layer 133, and the tunnel insulating layer 131 may respectively include the same materials as the blocking insulating layer BI, the data storage layer DS, and the tunnel insulating layer TI, described above with reference to FIG. 4. The memory layer 137 may be formed in a liner shape, and central regions of the channel holes 115 may be defined by the memory layer 137.

Thereafter, a first channel layer 141 may be formed on the surface of the memory layer 137, and then the channel structure 147 may be formed. The first channel layer 141 may include a semiconductor layer used as a channel area. For example, the first channel layer 141 may include undoped polysilicon.

In an embodiment, the first channel layer 141 may be formed in a liner shape, and the central regions of the channel holes 115 may include portions that are not filled with the first channel layer 141. When the first channel layer 141 is formed in a liner shape, the step of forming the channel structure 147 may include the step of filling the central regions of the channel holes 115 with a core insulating layer 143 on the first channel layer 141, the step of etching a portion of the core insulating layer 143 and defining a recess region in a portion of the central region of each channel hole 115, and the step of filling the recess region with a doped semiconductor layer 145. The core insulating layer 143 may include an oxide, and the doped semiconductor layer 145 may include a conductive dopant. The conductive dopant may include an n-type dopant for junctions. The conductive dopant may include a counter-doped p-type dopant.

In other embodiments, the first channel layer 141 may be formed to fill the central regions of the channel holes 115, wherein the core insulating layer 143 and the doped semiconductor layer 145 may be obviated. When the core insulating layer 143 and the doped semiconductor layer 145 are omitted, the step of forming the channel structure 147 may further include the step of doping the first channel layer 141 with the conductive dopant. In an embodiment, the channel structures 147 may each include a core insulating layer 143 penetrating at least a portion of the gate stacked body and having an end extending into the first substrate 101 as, for example, shown in FIG. 5C.

Referring to FIG. 5D, after the first mask pattern 121 of FIG. 5C is removed, a first insulating layer 151 may be formed.

Then, a slit 153 may be formed. The slit 153 may pass through the first insulating layer 151, and may also pass through the stacked structure of the first material layers 111 and the second material layers 113. The slit 153 may correspond to the slit SI illustrated in FIG. 4. Next, the second material layers 113 exposed through the slit 153 may be selectively removed, and thus horizontal spaces 155 may be defined. The horizontal spaces 155 may be defined between the first material layers 111 adjacent to each other in a vertical direction.

Referring to FIG. 5E, the horizontal spaces 155 illustrated in FIG. 5D may be filled with third material layers 157 through the slit 153. The third material layers 157 may be portions of the conductive patterns CP1 to CPn that have been described above with reference to FIG. 4. For example, the third material layers 157 may be a first conductive pattern CP1, which can be used as a drain select line, and second to n−1-th conductive patterns CP2 to CPn−1, which can be used as word lines. The third material layers 157 may fill the horizontal spaces 155 to enclose the channel structure 147 and the memory layer 137.

As described above, a gate stacked body 150 may be formed on the first substrate 101 by replacing the second material layers 113 as sacrificial layers with the third material layers 157 as conductive patterns. The gate stacked body 150 may include a structure in which the first material layers 111 as interlayer insulating layers and the third material layers 157 as conductive patterns are alternately stacked. The gate stacked body 150 may be at least partially penetrated by the channel structure 147, and the channel structure 147 may extend into the first substrate 101. The memory layer 137 may extend from an area between the channel structure 147 and the gate stacked body 150 to an area between the end of the channel structure 147 and the first substrate 101.

Through the processes described above with reference to FIGS. 5A to 5E, a memory block including the plurality of cell strings CS1 and CS2, described above with reference to FIG. 3, may be formed on the first substrate 101. As described above with reference to FIG. 3, each of the cell strings may include a drain select transistor DST and memory cells MC1 to MCn, which are connected in series to each other. The drain select transistor DST and the memory cells MC1 to MCn, described above with reference to FIG. 3, may be defined in intersection regions between the channel structure 147 of FIG. 5E and the third material layers 157 as the conductive patterns, and may be connected in series by the channel structure 147.

Next, a sidewall insulating layer 161 covering the sidewall of the gate stacked body 150 may be formed. Thereafter, a second insulating layer 163, extending to fill the slit 153 and to cover the sidewall insulating layer 161 and the first insulating layer 151, may be formed.

Referring to FIG. 5F, a third insulating layer 171 may be formed on the second insulating layer 163. Thereafter, contact plugs 173 which penetrate the third insulating layer 171 or penetrate at least portions of the third insulating layer 171 and the second insulating layer 163 may be formed. The contact plugs 173 may extend to contact the channel structure 147.

Next, a first line array 175 may be formed. The first line array 175 may be a bit line coupled to the contact plugs 173. Thereafter, a first insulating structure 181 covering the first line array 175 may be formed. The first insulating structure 181 may include two or more insulating layers 181A to 181D. First connection structures 185, 189, 191, and 193 may be embedded in the first insulating structure 181, and may be electrically connected to each other via contact plugs (not illustrated).

The first connection structures 185, 189, 191, and 193 may include a first bonding metal material 193 having a surface exposed to the outside of the first insulating structure 181.

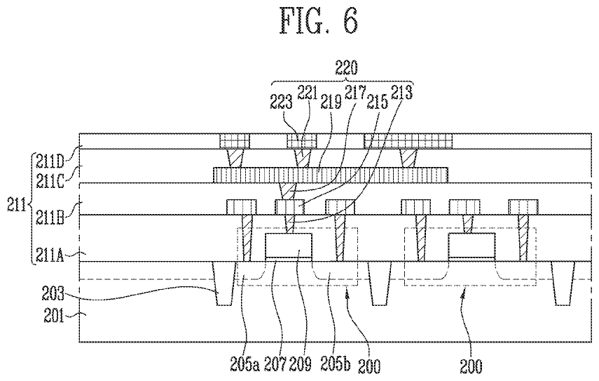

FIG. 6 is a sectional view for explaining the step of forming a CMOS circuit and second connection structures on a second substrate.

Referring to FIG. 6, a plurality of transistors 200 constituting a complementary metal oxide semiconductor (CMOS) circuit may be formed on a second substrate 201.

The second substrate 201 may be a bulk silicon substrate, a silicon-on-insulator substrate, a germanium substrate, a germanium-on-insulator substrate, a silicon-germanium substrate, or an epitaxial layer substrate formed using a selective epitaxial growth method.

The transistors 200 may be formed in respective active areas of the second substrate 201 separated by an isolation layer 203. Each of the transistors 200 may include a gate insulating layer 207 and a gate electrode 209 stacked in the active area corresponding thereto and junctions 205a and 205b formed in active areas disposed on both sides of the gate electrode 209. Each of the junctions 205a and 205b may include a conductive dopant for implementing a transistor corresponding thereto. Each of the junctions 205a and 205b may include at least one of an n-type dopant and a p-type dopant.

After the plurality of transistors 200 are formed, second connection structures 220 coupled to the transistors 200 constituting the CMOS circuit, and a second insulating structure 211 configured to cover the second connection structures 220 and the transistors 200 may be formed.

The second insulating structure 211 may include two or more insulating layers 211A to 211D. The second connection structures 220 may be embedded in the second insulating structure 211. Each of the second connection structures 220 may include a plurality of conductive patterns 213, 215, 217, 219, 221, and 223. The second insulating structure 211 and the second connection structures 220 may be changed in various forms without being limited to the example illustrated in the drawing.

The conductive patterns 213, 215, 217, 219, 221, and 223 included in each of the second connection structures 220 may include a second bonding metal material 223 having a surface exposed to the outside of the second insulating structure 211.

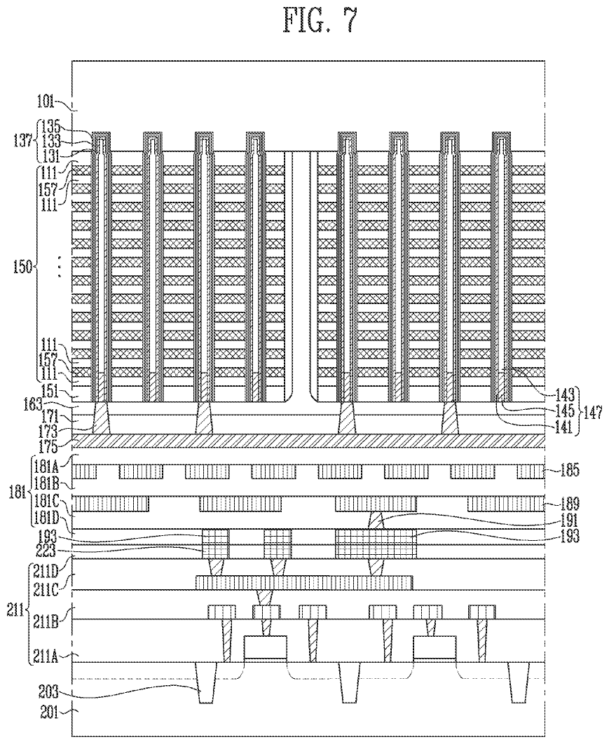

FIG. 7 is a sectional view for explaining the step of adhering the first connection structures and the second connection structures to each other.

Referring to FIG. 7, a first substrate 101 and a second substrate 201 are aligned such that a first bonding metal material 193 on the first substrate 101 and a second bonding metal material 223 on the second substrate 201 come into contact with each other. The first bonding metal material 193 and the second bonding metal material 223 may contain various types of metal materials, for example, copper.

Thereafter, the first bonding metal material 193 and the second bonding metal material 223 are adhered to each other. For this, after heat is applied to the first bonding metal material 193 and the second bonding metal material 223, the first bonding metal material 193 and the second bonding metal material 223 may be hardened. The present disclosure is not limited thereto, and various processes for coupling the first bonding metal material 193 and the second bonding metal material 223 to each other may be introduced.

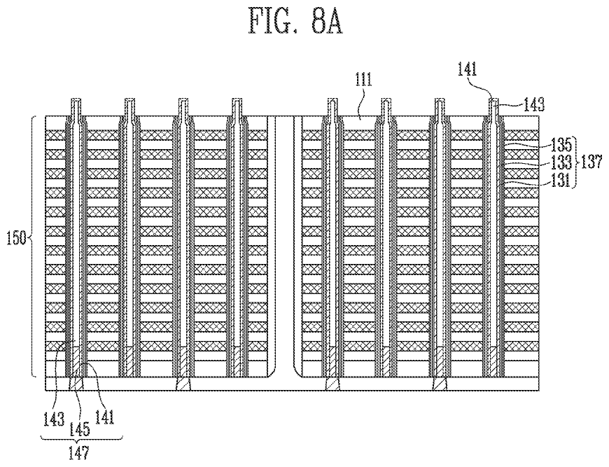

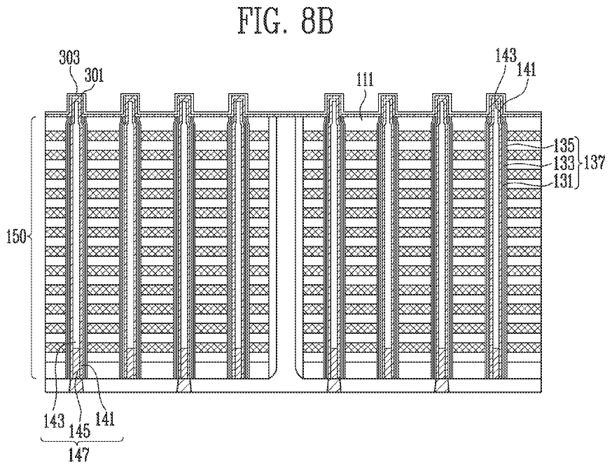

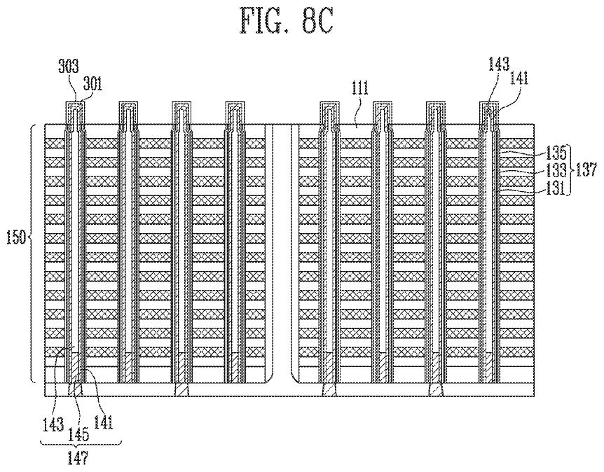

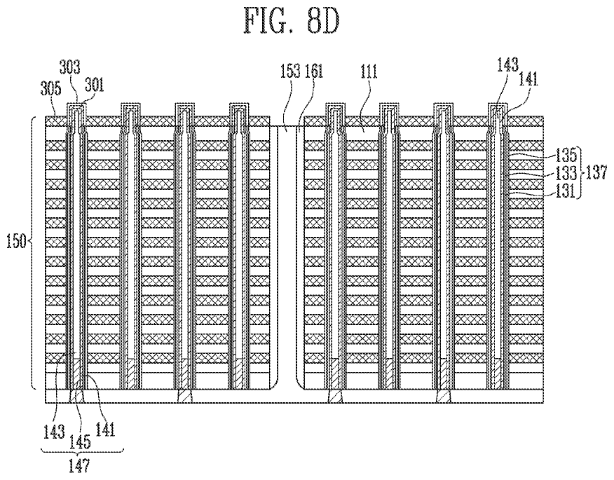

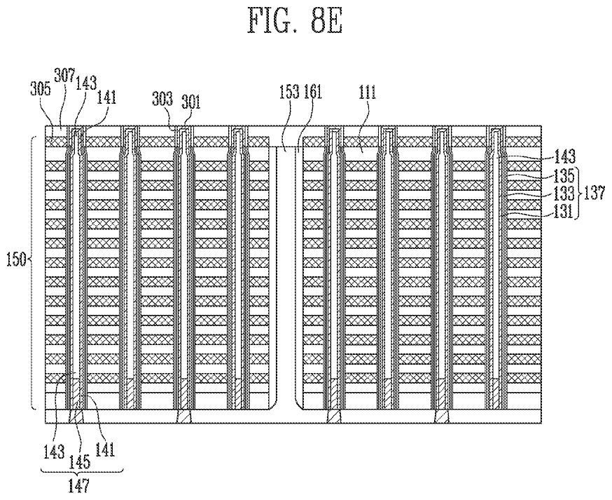

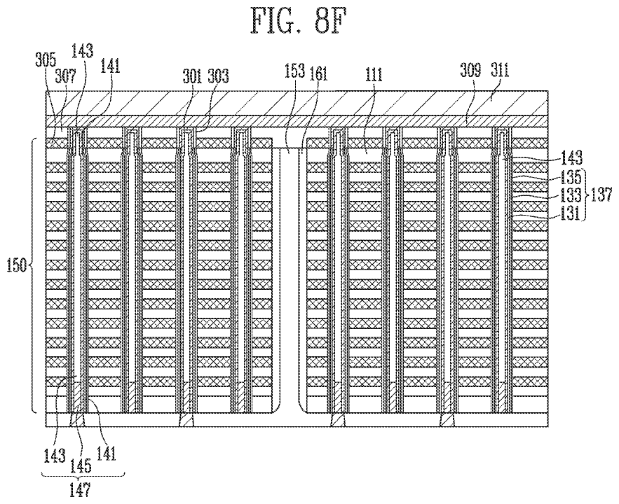

FIGS. 8A to 8F are sectional views for explaining the step of forming a source line structure coupled to a plurality of cell strings on a gate stacked body 150.

Referring to FIG. 8A, the first substrate 101 illustrated in FIG. 7 is removed. Due thereto, the memory layer 137 and the first channel layer 141 may protrude higher than the uppermost surface of the gate stacked body 150. In an embodiment, removing the first substrate 101 may cause the ends of the plurality of channel structures 147 to protrude from the gate stacked body as, for example, shown in FIG. 8A.

Thereafter, the memory layer 137 protruding higher than the uppermost surface of the gate stacked body 150 may be etched by performing an etching process, whereby the first channel layer 141 is exposed. In an embodiment, the first channel layer 141 may be exposed by removing the memory layer 137 from the protruding ends of the channel structures 147 as, for example, shown in FIG. 8A.

Referring to FIG. 8B, a second channel layer 301 and a gate insulating layer 303 are formed along the uppermost surface of the gate stacked body 150 and the surface of the protruding first channel layer 141. The second channel layer 301 may include a doped polysilicon layer. The gate insulating layer 303 may include an oxide layer.

Referring to FIG. 8C, an etching process is performed such that the second channel layer 301 and the gate insulating layer 303 remain only on the sidewall and the upper surface of the protruding first channel layer 141. That is, the gate insulating layer 303 and the second channel layer 301 formed on the uppermost surface of the gate stacked body 150 are etched and removed.

Thereafter, an additional oxidization process is performed, so an exposed portion of the end of the second channel layer 301 is additionally oxidized during the process for etching the gate insulating layer 303 and the second channel layer 301, thus preventing or mitigating the second channel layer 301 from being exposed.

In the above-described FIGS. 8B and 8C, illustrated is an embodiment in which the second channel layer 301 and the gate insulating layer 303 are formed along the uppermost surface of the gate stacked body 150 and the surface of the protruding first channel layer 141, after which an etching process is performed to etch both the gate insulating layer 303 and the second channel layer 301. In various embodiments, after the second channel layer 301 is formed along the uppermost surface of the gate stacked body 150 and the surface of the protruding first channel layer 141, an etching process may be performed such that the second channel layer 301 remains only on the surface of the protruding first channel layer 141, and the gate insulating layer 303 may be formed along the uppermost surface of the gate stacked body 150 and the surface of the second channel layer 301. Thereafter, an etching process may be performed, whereby the gate insulating layer 303 may remain to enclose the surface of the second channel layer 301.

Referring to FIG. 8D, a conductive layer is formed along the uppermost surface of the gate stacked body 150 and the sidewall and the upper surface of the gate insulating layer 303, and a conductive pattern 305 is formed by patterning the conductive layer to allow the conductive layer to remain only on the uppermost surface of the gate stacked body 150. The conductive pattern 305 may be used as the source select line SSL of FIG. 3. Also, the conductive layer formed on the slit 153 may be removed. Due thereto, the conductive pattern 305 may be disposed in spaces between gate insulating layers 303. The conductive pattern 305 may be formed to enclose the sidewalls of the gate insulating layers 303. The conductive pattern 305 may include various conductive materials, such as a doped silicon layer, a metal layer, a metal silicide layer, and a barrier layer, and may include two or more types of conductive materials.

Referring to FIG. 8E, an interlayer insulating layer 307 may be formed on the entire structure including the conductive pattern 305. The interlayer insulating layer 307 may be formed to cover the upper portions of all of the gate insulating layers 303.

Thereafter, an etching process may be performed to expose the second channel layer 301. For example, the etching process may be performed using a chemical mechanical polishing (CMP) process. For example, the interlayer insulating layer 307 and the gate insulating layer 303 may be etched using the CMP process such that the upper surface of the second channel layer 301 is exposed.

Referring to FIG. 8F, a first source layer 309 is formed along the interlayer insulating layer 307 and the exposed upper surface of the second channel layer 301. The first source layer 309 may be implemented as a doped polysilicon layer. The first source layer 309 may directly contact the upper surface of the second channel layer 301. Thereafter, a second source layer 311 may be formed along the upper surface of the first source layer 309, and the second source layer 311 may be formed of a metal material having low resistance. For example, the second source layer 311 may be formed of tungsten W, thus reducing the resistance of the source line structure. After the first source layer 309 is formed, a titanium (Ti) layer or a titanium nitride (TiN) layer may be further formed on the surface of the first source layer 309.

As described above, in accordance with an embodiment of the present disclosure, the first substrate is removed, after which the second channel layer and the gate insulating layer for a source select transistor may be formed along the surface of the protruding channel structure. The second channel layer is formed along the surface of the exposed channel structure, so a doped polysilicon layer may be formed, and thus the dopant concentration of the channel layer for the source select transistor may be controlled without requiring an ion implantation process and a diffusion process using heat treatment.

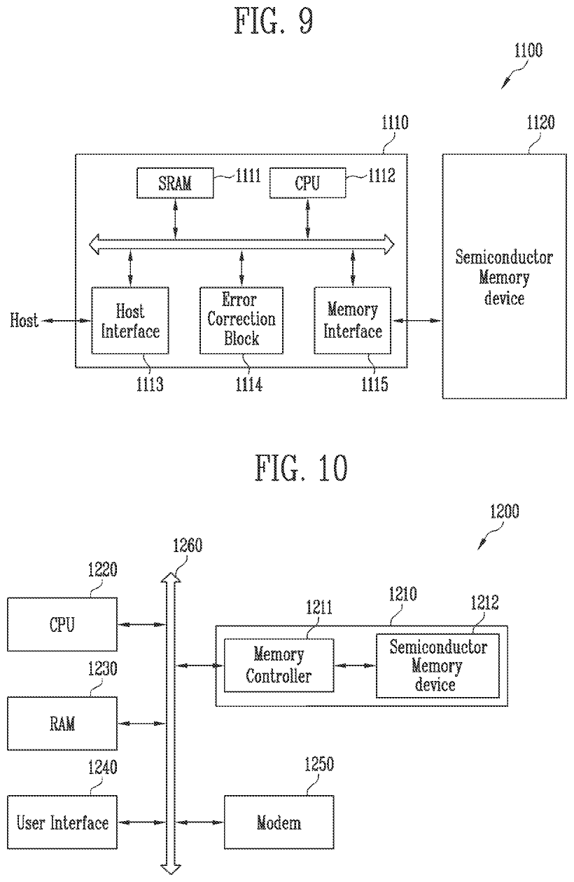

FIG. 9 is a block diagram illustrating the configuration of a memory system 1100 according to an embodiment of the present disclosure.

Referring to FIG. 9, the memory system 1100 includes a semiconductor memory device 1120 and a memory controller 1110.

The semiconductor memory device 1120 may be a multi-chip package composed of a plurality of flash memory chips. The semiconductor memory device 1120 may be the semiconductor memory devices described with reference to FIGS. 1 to 4.

The memory controller 1110 may control the semiconductor memory device 1120, and may include a static random access memory (SRAM) 1111, a central processing unit (CPU) 1112, a host interface 1113, an error correction block 1114, and a memory interface 1115. The SRAM 1111 may be used as a working memory of the CPU 1112, the CPU 1112 may perform overall control operations for data exchange of the memory controller 1110, and the host interface 1113 may be provided with a data interchange protocol of a host coupled to the memory system 1100. Further, the error correction block 1114 may detect and correct an error included in data that is read from the semiconductor memory device 1120, and the memory interface 1115 may interface with the semiconductor memory device 1120. In addition, the memory controller 1110 may further include a read only memory (ROM) or the like that stores code data for interfacing with the host.

The above-described memory system 1100 may be a memory card or a solid state drive (SSD) in which the semiconductor memory device 1120 and the memory controller 1110 are combined with each other. For example, when the memory system 1100 is an SSD, the memory controller 1110 may communicate with an external device (e.g., host) through one of various interface protocols, such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), and an Integrated Drive Electronics (IDE).

FIG. 10 is a block diagram illustrating the configuration of a computing system according to an embodiment of the present disclosure.

Referring to FIG. 10, the computing system 1200 according to an embodiment of the present disclosure may include a CPU 1220, a random access memory (RAM) 1230, a user interface 1240, a modem 1250, and a memory system 1210, which are electrically connected to a system bus 1260. Also, when the computing system 1200 is a mobile device, it may further include a battery for supplying an operating voltage to the computing system 1200, and may further include an application chip set, a camera image processor (CIS), a mobile DRAM, etc.

In accordance with the present disclosure, a channel structure protruding by penetrating at least a portion of a gate stacked body is formed, after which a channel layer and a gate insulating layer for a select transistor may be formed on the sidewall of the protruding channel structure. Due thereto, since impurity concentration of the channel layer for the select transistor may be adjusted without requiring an ion implantation process and a heat treatment process, the threshold voltage of the select transistor may be controlled.

While the embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

What is claimed is:

1. A semiconductor memory device, comprising:
a gate stacked body including a plurality of interlayer insulating layers and a plurality of conductive patterns that are alternately stacked in a vertical direction on a substrate;
a channel structure penetrating at least a portion of the gate stacked body, and an upper surface of the channel structure left exposed by the gate stacked body;
a memory layer configured to enclose a sidewall of the channel structure; and
a source line structure formed on the gate stacked body to contact the upper surface of the channel structure,
wherein the channel structure comprises:
a first channel layer extending in a vertical direction; and
a second channel layer configured to enclose a sidewall of the first channel layer adjacent to an uppermost conductive pattern, among the plurality of conductive patterns.

2. The semiconductor memory device according to claim 1, wherein the upper surface of the channel structure is a surface of the second channel layer.

3. The semiconductor memory device according to claim 1, further comprising:
a gate insulating layer disposed between the uppermost conductive pattern and the second channel layer.

4. The semiconductor memory device according to claim 3, wherein the memory layer is disposed between other conductive patterns, among the plurality of conductive patterns, and the first channel layer.

5. The semiconductor memory device according to claim 4, wherein the memory layer comprises:
a tunnel insulating layer configured to enclose an outer wall of the first channel layer;
a data storage layer configured to enclose an outer wall of the tunnel insulating layer; and
a blocking insulating layer configured to enclose an outer wall of the data storage layer.

6. The semiconductor memory device according to claim 1, wherein the first channel layer is an undoped polysilicon layer.

7. The semiconductor memory device according to claim 1, wherein the second channel layer is a doped polysilicon layer.

8. The semiconductor memory device according to claim 1, wherein the source line structure comprises:
a first source layer formed along an upper portion of the gate stacked body and the upper surface of the channel structure; and
a second source layer formed on the first source layer.

9. A semiconductor memory device, comprising:
a gate stacked body including a plurality of interlayer insulating layers and a plurality of conductive patterns that are alternately stacked in a vertical direction on a substrate;
a channel structure penetrating at least a portion of the gate stacked body, and an upper surface of the channel structure left exposed by the gate stacked body;
a memory layer configured to enclose a sidewall of the channel structure; and
a source line structure formed on the gate stacked body to contact the upper surface of the channel structure,
wherein the channel structure comprises:
a core insulating layer extending in the vertical direction;
a first channel layer configured to enclose an outer wall of the core insulating layer; and
a second channel layer configured to enclose a sidewall of the first channel layer adjacent to an uppermost conductive pattern, among the plurality of conductive patterns, and
wherein the memory layer comprises:
a gate insulating layer disposed between the second channel layer and the uppermost conductive pattern.

10. The semiconductor memory device according to claim 9, wherein the upper surface of the channel structure is a surface of the second channel layer.

11. The semiconductor memory device according to claim 9, wherein the memory layer further comprises:
a tunnel insulating layer configured to enclose an outer wall of the first channel layer;
a data storage layer configured to enclose an outer wall of the tunnel insulating layer; and
a blocking insulating layer configured to enclose an outer wall of the data storage layer.

12. The semiconductor memory device according to claim 9, wherein the first channel layer is an undoped polysilicon layer and the second channel layer is a doped polysilicon layer.

13. A method of manufacturing a semiconductor memory device, comprising:
forming a gate stacked body including a plurality of interlayer insulating layers and a plurality of conductive patterns that are alternately stacked in a vertical direction on a substrate;
forming a plurality of channel structures, each including a core insulating layer penetrating at least a portion of the gate stacked body and having an end extending into the first substrate, a first channel layer configured to enclose a sidewall and the end of the core insulating layer, and a memory layer extending from an area between the first channel layer and the gate stacked body to an area between an end of the channel layer and the first substrate;
causing ends of the plurality of channel structures to protrude from the gate stacked body by removing the first substrate;
exposing the first channel layer by removing the memory layer, among the protruding ends of the channel structures;
sequentially forming a second channel layer and a gate insulating layer along a surface of the exposed first channel layer; and
forming a conductive pattern on the gate stacked body between the protruding channel structures.

14. The method according to claim 13, wherein the first channel layer is implemented as an undoped polysilicon layer and the second channel layer is implemented as a doped polysilicon layer.

15. The method according to claim 13, wherein forming the second channel layer and the gate insulating layer comprises:
forming the second channel layer along the surface of the exposed first channel layer and an upper surface of the gate stacked body;
forming the gate insulating layer along an upper surface of the second channel layer; and
removing the gate insulating layer and the second channel layer on the gate stacked body by performing an etching process.

16. The method according to claim 13, further comprising:
forming an insulating layer on an entire structure including the conductive pattern, and thereafter performing an etching process such that the second channel layer is exposed; and
forming a source line structure on the exposed second channel layer and the insulating layer.

17. The method according to claim 16, wherein forming the source line structure comprises:
forming a first source layer on the second channel layer and the insulating layer; and
forming a second source layer on the first source layer.

18. The method according to claim 17, wherein the first source layer is implemented as a doped polysilicon layer and the second source layer is implemented as a tungsten layer.
